(19) United States
(12) Patent Application Publication
(10) Pub. No.: US 2007/0151590 A1
(43) Pub. Date: Jul. 5, 2007

(54) Prismatic type lithium secondary battery and manufacturing thereof

(75) Inventor: Shingun Kang, Yongin-si (KR)

Correspondence Address: STEIN, MCEWEN & BUI, LLP, 1400 EYE STREET, NW, SUITE 300, WASHINGTON, DC, 20005, US

(73) Assignee: Samsung SDI Co., Ltd., Suwon-si (KR)

(21) Appl. No.: 11/647,333

(22) Filed: Dec. 29, 2006

(30) Foreign Application Priority Data
Dec. 29, 2005 (KR) 2005-134522

(51) Int. Cl. H01L 35/34

(52) U.S. Cl. 136/201

(57) ABSTRACT

A prismatic type lithium secondary battery, including an electrode assembly including an anode plate, a cathode plate, and a separator wound together, a can to receive the electrode assembly via an opening in an upper end thereof, a cap assembly to seal the opening of the can, an insulating case mounted on an upper portion of the electrode assembly once the electrode assembly is inside the can, and a stopping unit, formed in sides of the can to protrude toward the interior of the can, including a support surface to support the cap assembly and a surface to engage with the insulating case.

### CROSS-REFERENCE TO RELATED APPLICATION

This application claims the benefit of Korean Application No. 2005-134522, filed Dec. 29, 2005 in the Korean Intellectual Property Office, the disclosure of which is incorporated herein by reference.

### BACKGROUND OF THE INVENTION

1. Field of the Invention

Aspects of the present invention relate to a prismatic type lithium secondary battery and, more particularly, to a prismatic type lithium secondary battery and a method of processing a prismatic type lithium secondary battery which simplifies the molding process of the receiving portion of the cap assembly body that seals an upper opening of a can in a prismatic type can.

2. Description of the Related Art

A secondary battery is a term for a battery that is capable of being electrically charged and discharged. A primary battery, on the other hand, is not capable of being electrically discharged. A secondary battery may be used in the field of highly technical electronic devices, such as a cellular phone, a note book computer, and a cam coder, etc.

In particular, a lithium secondary battery has an operating voltage of 3.6 volts, which is approximately 3 times higher than a Nickel-Cadmium battery or a Nickel-Hydrogen battery, each of which may be used as a power source for electronic devices. The lithium secondary battery also has a high characteristic energy density per unit weight.

The lithium secondary battery in practical use employs a carbon-based material, such as graphite, as a negative electrode, a lithium-containing oxide, such as LiCoO₂, as a positive electrode, and an organic solvent (e.g., cyclic carbonate, such as ethylene carbonate, a chain carbonate, such as dimethyl carbonate and the like, in which an electrolyte salt, such as LiPF₆ is dissolved, for the electrolyte solution). In such lithium secondary batteries, since a lithium ion moves between the positive electrode and the negative electrode during charging and discharging processes, the energy density of each battery is determined depending on the specific capacity of positive electrode, the specific capacity of negative electrode, the battery specific capacity of positive electrode, the specific capacity of negative electrode, the battery voltage, and the type of the electrolyte solution (i.e., the polymer number of the electrolyte solution).

In addition, lithium secondary batteries are produced in many various shapes, such as cylinders, prisms, and/or pouches.

FIG. 1 is a partial sectional view of a conventional prismatic type lithium secondary battery 10. Here, the prismatic type lithium secondary battery 10 includes a can 11, an electrode assembly 12, which is received in the can 11, and a cap assembly 20, which seals and which is connected to an upper opening of the can 11. The can 11 is a prismatic case of a metal material having an inside space. The electrode assembly 12 is a winding in which an anode plate 13, a separator 14 and cathode plate 15 are wound together. An anode lead 16 and a cathode lead 17 are connected to and serve as outlets for the anode plate 13 and cathode plate 15, respectively.

The cap assembly 20 includes a cap plate 21, which is coupled to the upper portion of the can 11. A cathode terminal 23 is inserted through the cap plate 21 via a gasket 22. An insulation plate 24 is mounted on the lower portion of the cap plate 21. A terminal plate 25, which communicates with the cathode terminal 23, is installed on a lower portion of the cap plate 24. An electrolyte liquid injecting hole 26, to serve as part of an electrolyte injection path to the inside of the can 11, is formed on the cap plate 21 and is coupled with a ball 27. The anode lead 16 is directly connected to the power surface of the cap plate 21 and the cathode lead 17 is electrically coupled to the cathode terminal 23 via the terminal plate 25. An insulating case 18 is installed on an upper portion of the electrode assembly 12 inside of the can 11 to insulate the electrode assembly 12 from the cap assembly 20. A lead hole 18a, which provides an outlet for the cathode lead 17 and an electrolyte liquid inlet hole 18b, which allows for a flow of the electrolyte liquid therethrough, are formed on the insulating case 18.

The prismatic type lithium secondary battery 10, constructed as described above, therefore includes the jelly roll type electrode assembly 12 inserted inside of the can 11, the insulating case 18 mounted on the upper surface of the electrode assembly 12, and the cap assembly 20 mounted on a stage differential member 11a, which is formed on an upper end of the can 11.

The cap assembly 20 is welded to the anode lead at a lower surface of the cap plate 21. The cathode terminal 23 is welded to the cathode lead. The cap assembly 20 is welded to the can 11 and the electrolyte liquid is injected through the electrolyte liquid injecting hole 26. The electrolyte liquid injecting hole 26 is then sealed by the ball 27.

However, according to the conventional prismatic type lithium secondary battery, the stage differential member 11a should be formed to allow for a mounting of the cap assembly 20 on the peripherals of the opening in the upper end of the can 11. Therefore, a molding process of the stage differential member is required to be added to the process. As such, total production costs of the battery increase, and problems with the mounting of the cap assembly 20 appear.

Also, according to the conventional prismatic type lithium secondary battery, the insulating case 18, which is mounted on the upper portion of the electrode assembly, includes an extending part 18c to improve sealing properties of the insulating case 18 with the can. As a result, a size of the insulating case is increased and, therefore, a practical capacity of the battery is diminished.

### SUMMARY OF THE INVENTION

Accordingly, it is an aspect of the present invention to simplify the process of the can production and to cause a decrease in the cost of the production thereof. Another aspect of the present invention is to relatively easily secure and maintain the proper shape of the cap assembly when the cap assembly is attached to the stage differential member of the can. A further aspect of the present invention is to provide an increased capacity of the battery by simplifying the insulating case of the electrode assembly.

A prismatic type lithium secondary battery according an embodiment of the present invention includes an electrode assembly including an anode plate, a cathode plate, and a separator wound together; a can to receive the electrode assembly via an opening in an upper end thereof; a cap assembly to seal the opening of the can; an insulating case mounted on an upper portion of the electrode assembly once the electrode assembly is inside the can; and a stopping unit, formed in sides of the can to protrude toward the interior of the can, including a support surface to support the cap assembly and a surface to engage with the insulating case.

The stopping unit comprises stoppers formed as embossed moldings in opposite sides of the can, each of the stoppers including a support surface.

The stoppers are formed as circles, prisms, or are streamlined.

The insulating case comprises a flat plate mounted to be engaged with the lower surface of the stopper.

The process of the prismatic type lithium secondary battery according to an embodiment of the present invention comprises inserting a jelly roll type electrode assembly into a can; forming a stopper on surfaces of the can above the electrode assembly; mounting an insulating case to an upper portion of the electrode assembly to engage with lower surfaces of the stopper; and mounting a cap assembly on upper surfaces of the stopper

Thus, the stage differential member of the can is not required. The stopper is formed by compression. As such the process is simplified.

Additional and/or other aspects and advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a partial sectional view of a conventional prismatic type lithium secondary battery;

FIG. 2 is a separated schematic perspective view of a prismatic type lithium secondary battery according to an embodiment of the present invention;

FIG. 3A is a plane view of a prismatic type can of FIG. 2;

FIG. 3B is a cross-sectional view in along the line A-A of FIG. 3A;

FIG. 4 is a cross-sectional view of the prismatic type lithium secondary battery of FIG. 2;

FIG. 5A and FIG. 5B are plane views of the prismatic type can of FIG. 3A;

FIG. 6 is a plane view of a prismatic type can according to another embodiment of the present invention

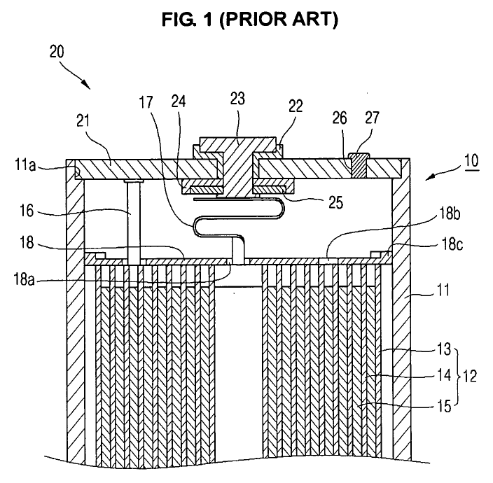

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

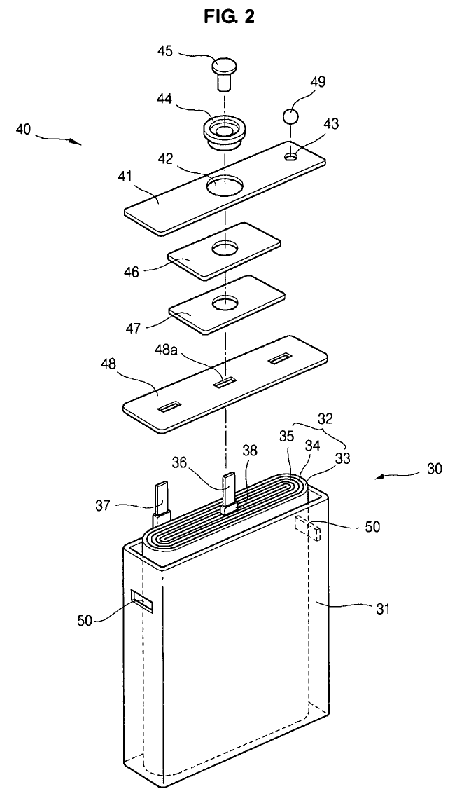

With reference to FIG. 2, the prismatic type lithium secondary battery 30, according to an embodiment of the present invention, includes a can 31, an electrode assembly 32, which is received in the can 31, and a cap assembly 40 coupled to an upper portion of the can 31. The can 31 is formed with a hollow cavity and is metallic. Therefore, the can 31 may operate as a terminal. A stopper 50 protrudes towards an interior of the can 31 on opposite sides of an upper part of the can 31.

The stoppers 50 are each formed as a result of an embossing treatment. The embossing treatment is a form of a compressing process in press processing that can be completed rapidly and with lowered costs.

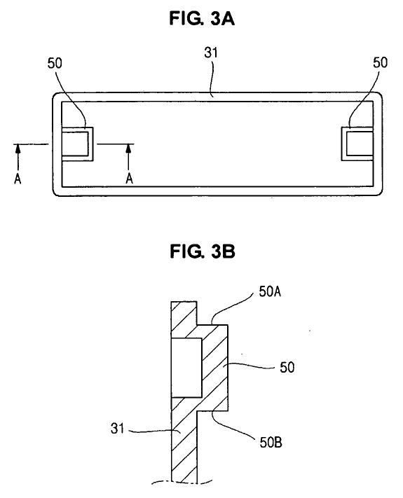

Referring now to FIGS. 3A and 3B, the stopper 50 is shown protruding from opposite surfaces of the can 31 towards the interior of the can 31. The left and right side stoppers 50 each include an upper surface 50A and lower surface 50B. The cap assembly 40 is attached to the can 31 substantially horizontally along the upper surfaces 50A of each of the stoppers 50, which provide support for the cap assembly 40, such that the cap assembly 40 is substantially parallel with a width of the can 31. Of course, it is understood that the cap assembly 40 need not be attached to the can 31 substantially horizontally and that other formations and arrangements are possible.

An upper surface of the insulating case 48 is engaged with the lower surface 50B of each of the stoppers 50. Therefore, since a size of the left and right side stoppers 50 may be relatively easily controlled by the press treatment system, the can 31 and the stoppers 50 may be formed to have precise respective heights in accordance with a capacity of the battery.

The electrode assembly 32, which is received in the interior of the can 31, includes a cathode plate 33, an anode plate 35, and a separator 34. The cathode plate 33, the anode plate 35, and the separator 34 (e.g., a strip or strips of insulating material) are successively laminated and wound into a jelly roll. In accordance with an embodiment of the invention, the separator 34 is plural in number and insulates the cathode plate 33 and the anode plate 35 from one another.

The cap assembly 40 seals the opening of the can 31 and includes a cap plate 41. The cap plate 41 is flat and metallic and has a size and shape that corresponds to the opening of the can 31. A terminal through-hole 42 is formed near a center of the cap plate 41 with a predetermined size. An electrolyte liquid injecting hole 43 is formed on a side of the cap plate 41. A ball 49 may be used to seal the electrolyte liquid injection hole 43 once an electrolyte has been introduced to the interior of the can 31.

A cathode terminal 45 can be inserted through terminal through-hole 42. A gasket 44, such as a tube, is installed between an outer surface of the cathode terminal 45 and the through-hole 42 of the cap plate 41.

An insulating plate 46 is installed on the lower surface of the cap plate 41. A terminal plate 47 is installed on lower surface of the insulating plate 46. Both the insulating plate 46 and the terminal plate 47 include through-holes through which the cathode terminal 45 is inserted. The lower part of the cathode terminal 45 is electrically connected to the terminal plate 47.

Since, the insulating case 48 is installed on an upper part of the electrode assembly 32, the insulating case 48 electrically insulates the cap assembly 40 and the electrode assembly 32 from one another and serves as a flow path for the electrolyte liquid injected through the electrolyte injecting hole 43. According to an embodiment of the invention, the insulating case 48 comprises high polymer resin, and may include poly-propylene.

The insulating case 48 installed in close engagement with the lower surface 50B of the stopper 50 does not require an extending part as in the conventional battery and may be formed as a flat plate. Therefore the shape of the insulating case 48 is relatively simple, and yields space inside of the battery cell such that a capacity of the battery is increased.

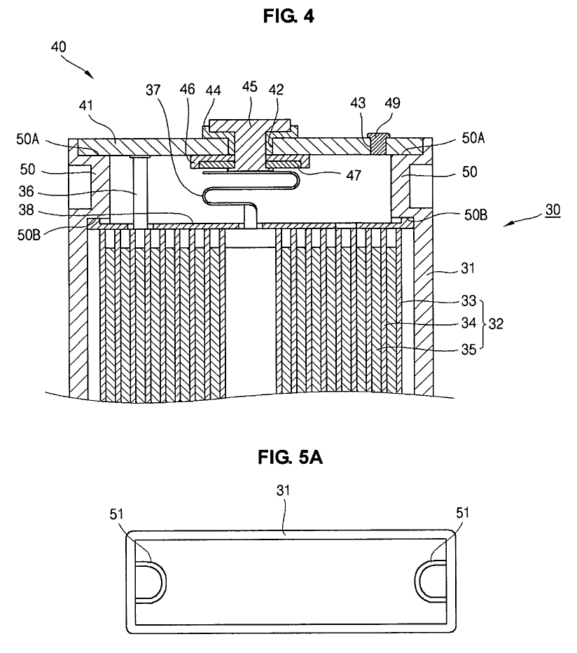

Referring to FIGS. 2 and 4, the procedure of the assembly of the prismatic type secondary battery 30 will be described. The cathode plate 33, the separator 34, and the anode plate 35 are laminated and wound into a jelly-roll. The wound electrode assembly 32 is then inserted into a can 31. A pair of embossed stoppers 50 is then formed in the interior of the can 31 by a press treatment using a press machine on the upper end of both side surface portions of the can 31.

The insulating case 48 is then mounted on the upper portion of the electrode assembly 32. The insulating case 48 may be flexible and may be made from poly-propylene etc. Thus, a form of the insulating case 48 may temporarily change when the insulating case 48 is inserted in the can 31. Because an edge of the insulating case 48 is closely engaged with the lower surface 50B of the stopper 50, the insulating case 48 insulates the electrode assembly.

The cap plate 41 is welded to the can 31, and the electrolyte liquid is injected into the interior of the can 31. The electrolyte injection hole 43 is evacuated and sealed with a vacuum sealing device after a predetermined quantity of electrolyte is injected into the can 31. A cover plug 49 is then welded onto the injection hole 43.

The cap plate 41 of the cap assembly 40 is welded onto the upper surfaces 50A of the left and right side stoppers 50 of the can 31. As such, the cap assembly 40 and the insulating case 48 are maintained at a constant distance from one another. The anode lead 37 is electrically insulated from the cathode terminal 45, the cathode lead 36, and the cathode tab 38. Conversely, the cathode terminal 45, the cathode lead 36, and the cathode tab 38 remain electrically connected.

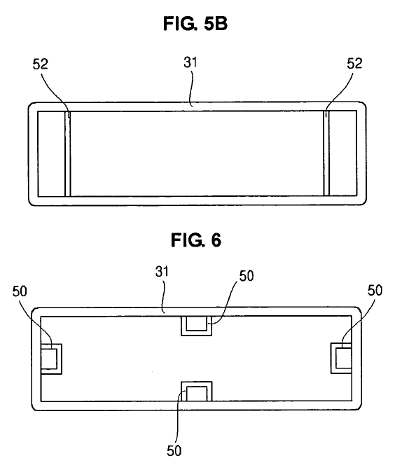

FIGS. 5A and 5B are plane views of the prismatic type can of FIG. 3A. As shown in FIG. 5A, the stoppers 50 are formed as half-circles 51 protruding towards an interior of the can 31. Meanwhile, as shown in FIG. 5B, the stoppers 50 are formed as rectangular shapes 52 protruding towards an interior of the can 31. According to additional embodiments of the invention, the stoppers 50 may be any shape that provides support for both the cap assembly 40 and the insulating case 48.

FIG. 6 is a plane view of the can 31 according to another embodiment of the present invention. Here, the stoppers 50 are formed on an inside of the both of the shorter sides of the can 31 and additional stoppers 50 are formed in the longer sides of the can 31. Thus, the supporting area, which supports the cap assembly 40, is broadened by the additionally formed stoppers 50. Therefore the supporting of the cap assembly 40 is additionally stabilized.

As is described above, a prismatic type lithium secondary battery according to aspects of the present invention may lead to a decrease in production costs by simplifying the molding process of the receiving portion of the cap assembly, results in the cap assembly being shaped and leveled appropriately, and provides for an increased capacity of the battery.

Although a few embodiments of the present invention have been shown and described, it would be appreciated by those skilled in the art that changes may be made in these embodiments without departing from the principles and spirit of the invention, the scope of which is defined in the claims and their equivalents.

What is claimed is:

1. A prismatic type lithium secondary battery, comprising:
an electrode assembly including an anode plate, a cathode plate, and a separator wound together;
a can to receive the electrode assembly via an opening in an upper end thereof;
a cap assembly to seal the opening of the can;
an insulating case mounted on an upper portion of the electrode assembly once the electrode assembly is inside the can; and
a stopping unit, formed in sides of the can to protrude toward the interior of the can, including a support surface to support the cap assembly and a surface to engage with the insulating case.

2. The secondary battery according to claim 1, wherein the stopping unit comprises stoppers formed as embossed moldings in opposite sides of the can, each of the stoppers including a support surface.

3. The secondary battery according to claim 1, wherein the support surface is flat, such that the cap assembly is sealed to the can in a position which is substantially parallel with a width of the can.

4. The secondary battery according to claim 2, wherein the support surfaces are each flat, such that the cap assembly is sealed to the can in a position which is substantially parallel with a width of the can.

5. The secondary battery according to claim 2, wherein the opposite sides are the shorter sides of the can.

6. The secondary battery according to claim 5, wherein the stopping unit further comprises stoppers formed as embossed moldings in opposite long sides of the can, each of the stoppers including a support surface.

7. The secondary battery according to claim 2, wherein the stoppers are circular.

8. The secondary battery according to claim 2, wherein the stoppers are rectangular.

9. The secondary battery according to claim 2, wherein the stoppers are streamlined.

10. The secondary battery according to claim 1, wherein the insulating case comprises a substantially flat plate.

11. The secondary battery according to claim 1, wherein the insulating case engages with lower surfaces of the stopping unit.

12. A process of manufacturing a prismatic type lithium secondary battery comprising:
inserting a jelly roll type electrode assembly into a can;
forming a stopper on surfaces of the can above the electrode assembly;
mounting an insulating case to an upper portion of the electrode assembly to engage with lower surfaces of the stopper; and
mounting a cap assembly on upper surfaces of the stopper.

13. The process according to claim 9, wherein the forming of the stopper comprises a compression treatment during a pressing procedure.

14. A battery, in which an electrode assembly on which an insulating case is mounted is received in a can that is enclosed by a cap assembly, comprising at least a pair of stoppers formed in opposing sides of the can between the insulating case and the cap assembly, each of the stoppers including a supporting surface to support the cap assembly and a lower surface to engage with the insulating case.

15. The battery according to claim 14, wherein the stoppers comprise embossed moldings.

16. The battery according to claim 14, wherein the stoppers are circular.

17. The battery according to claim 14, wherein the stoppers are rectangular.

18. The battery according to claim 14, wherein the insulating case comprises a substantially flat plate.

19. A process of manufacturing a battery comprising:
inserting a jelly roll type electrode assembly into a can;
mounting an insulating case to an upper portion of the electrode assembly;
forming a stopper on surfaces of the can above the electrode assembly such that lower surfaces of the stopper engage with the insulating case; and
mounting a cap assembly on upper surfaces of the stopper.

20. The process according to claim 19, wherein the forming of the stopper comprises a compression treatment.
